(19) United States
(12) Patent Application Publication
(10) Pub. No.: US 2013/0327377 A1
(43) Pub. Date: Dec. 12, 2013

(54) Thin Film Chalcogenide Photovoltaic Device and Method for Forming the Same

(71) Applicants: Ching Ting, Miaoli County (TW); Feng-Yu Yang, Miaoli County (TW)

(72) Inventors: Ching Ting, Miaoli County (TW); Feng-Yu Yang, Miaoli County (TW)

(21) Appl. No.: 13/490,440

(22) Filed: Jun. 6, 2012

(51) Int. Cl. H01L 51/44; H01L 51/48; B82Y 15/00; B82Y 40/00

(52) U.S. Cl. 136/255; 438/95; 257/E51.015; 977/735; 977/742

(57) ABSTRACT

A thin film chalcogenide photovoltaic device and method for forming the same are disclosed. The thin film chalcogenide photovoltaic device includes a first electrode, a second electrode and an active layer disposed between the first electrode and the second electrode, wherein the active layer includes a p-type chalcogenide semiconductor layer, an n-type inorganic semiconductor layer, and an n-type carbon-containing material layer formed between the p-type chalcogenide semiconductor layer and the n-type inorganic semiconductor layer.

### BACKGROUND

Renewable energy is getting more and more important since energy shortage nowadays. Main source of energy in highly-developed countries is fossil fuel, such as fuel, coat and natural gas. The resource of fossil fuel is limited and expected to be exhausted in several ten years. Another kind of main source is nuclear energy, however, it is problematic due to its potential damage to environment. Renewable energy includes wind energy, hydroelectric, solar energy, geothermal energy, biofuel, etc. Among those different kinds of renewable energies, solar energy is superior to others since it can be used at any place worldwide and without pollution, and attracts people's attention in recent years.

To date, crystalline silicon photovoltaic device is the main product which utilizes solar energy. Crystalline silicon photovoltaic device is made of silicon wafers and can convert sunlight into electricity. Crystalline silicon photovoltaic device is still far from common practice since its material and manufacturing cost are high and is not comparable to grid electricity.

Thin film photovoltaic device is expected to replace crystalline silicon photovoltaic device in the future since it can be made on a foreign substrate, such as glass, that can reduce the manufacturing cost. Besides, thin film photovoltaic device can be made as a transparent or flexible device which provides multiple applications. Transparent thin film photovoltaic device can be built into glass windows of buildings. A glass window like this is capable of passing sunlight into the building and also transforming part of the sunlight into electricity. Flexible thin film photovoltaic device can be mass-produced with a roll-to-roll process and the manufacturing cost can be further reduced. In addition, flexible thin film photovoltaic device is portable, light weight and high design factor.

Current material for thin film photovoltaic devices includes amorphous silicon (a-Si), cadmium telluride (CdTe), copper indium diselenide (CIS) and copper indium gallium diselenide (CIGS). Currently, conversion efficiency of a-Si thin film photovoltaic device is around 10% while conversion energy of crystalline silicon photovoltaic device is around 20%. The conversion efficiency of a-Si thin film photovoltaic device is limited by it material characteristic and Staebler-Wronski effect, i.e., the conversion efficiency is dropped when the a-Si thin film is continuously exposed to light. Therefore, it is not comparable with crystalline silicon photovoltaic device. By contrast, chalcogenide semiconductor photovoltaic devices, such as CdTe, CIS and CIGS thin film photovoltaic device each respectively includes conversion efficiency around 13%, 18%, and 20% and can be further improved to achieve a higher level.

Thus, researches have been focused on the target of increasing conversion efficiency of chalcogenide semiconductor photovoltaic devices in order to make it become a commercial product.

### SUMMARY

The present application provides a thin film chalcogenide photovoltaic device, including a first electrode, a second electrode and an active layer disposed between the first electrode and the second electrode, wherein the active layer includes a p-type chalcogenide semiconductor layer, an n-type inorganic semiconductor layer, and an n-type carbon-containing material layer formed between the p-type chalcogenide semiconductor layer and the n-type inorganic semiconductor layer.

The present application also provides a method for manufacturing a thin film chalcogenide photovoltaic device. The method includes steps forming a p-type chalcogenide semiconductor layer on a first electrode, forming an n-type carbon-containing material layer on at least a portion of the p-type chalcogenide semiconductor layer to form a composite layer constituted by the n-type carbon material layer and the p-type chalcogenide semiconductor layer, forming an n-type inorganic semiconductor layer on the composite layer, and forming a second electrode on the n-type inorganic layer.

### BRIEF DESCRIPTION OF THE DRAWINGS

The above and other objects, features and other advantages of the present application will be more clearly understood from the following detailed description taken in conjunction with the accompanying drawings, in which:

FIG. 1 is a front view of a conventional thin film chalcogenide photovoltaic device.

FIG. 2 is a SEM picture of CZTS thin film.

FIG. 3 is a front view of the thin film chalcogenide photovoltaic device of the present application.

FIG. 4 is a flow chart of a method of forming the thin film chalcogenide photovoltaic device according to an embodiment of the present application.

FIGS. 5a to 5c are enlarged sectional views of the thin film chalcogenide photovoltaic device of the present application.

### DETAILED DESCRIPTION

### Definitions

The following definitions are provided to facilitate understanding of certain terms used herein and are not meant to limit the scope of the present disclosure.

“Chalcogen” refers to group VIA element of periodic table. Preferably, the term “chalcogen” refers to sulfur, selenium and tellurium.

“Chalcogenide” refers to a chemical compound containing at least one chalcogen. Preferably, the term “chalcogenide” refers to sulfides, selenides and tellurides.

“Chalcogenide semiconductor film”, in a broad sense, refers to binary, ternary and quaternary chalcogenide compound semiconductor materials. Example of the binary chalcogenide compound semiconductor materials includes II-VI compound semiconductor and IV-VI compound semiconductor materials. The ternary chalcogenide compound semiconductor materials include I-III-VI compound semiconductor materials. The quaternary chalcogenide compound semiconductor materials include I-II-IV-VI compound semiconductor materials.

“CIS”, in a broad sense, refers to I-III-VI compound semiconductor materials. Preferably, the term “CIS” refers a copper indium selenide compound of the formula: e.g. CuIn(SeₓS₁₋ₓ)₂, wherein 0<x<1. The term “CIS” further includes copper indium selenide compounds with fractional stoichiometries, e.g., CuIn(Se_{0.65}S_{0.35})₂.

“CIGS” in a broad sense, refers to I-III-VI compound semiconductor materials. In one embodiment of the present application, “CIGS” refers a copper indium gallium selenide compound of the formula, e.g., CuInₓGa₁₋ₓSe₂, where 0<x<1. The term “CIGS” further includes copper indium gallium selenide compound with fractional stoichiometries, e.g., Cu_{0.9}In_{0.7}Ga_{0.3}Se₂,

“CZTS” in a broad sense, refers to I-II-IV-VI compound semiconductor materials. Preferably, the term “CZTS” refers a copper zinc tin sulfide/selenide compound of the formula: e.g. Cuₐ(Zn_{1-b}Sn_{b})(Se_{1-c}S_{c})₂, wherein 0<a<1, 0<b<1, 0≦c≦1. The term “CZTS” further includes copper zinc tin sulfide/selenide compounds with fractional stoichiometries, e.g., Cu_{1.94}Zn_{0.63}Sn_{1.3}S₄. Further, I-II-IV-VI compound semiconductor materials include I-II-IV-IV-VI compound semiconductor materials, such as copper zinc tin germanium sulfide, and I-II-IV-IV-VI-VI compound semiconductor materials such as copper zinc tin germanium sulfide selenide.

“II-VI compound semiconductor” refers to compound semiconductor materials composed of group IIA element and group VIA element of periodic table, such as cadmium telluride (CdTe).

“IV-VI compound semiconductor” refers to compound semiconductor materials composed of group IVA element and group VIA element of periodic table, such as tin sulfide (SnS).

“I-III-VI compound semiconductor” refers to compound semiconductor materials composed of group IB element, group IIIA element and group VIA element of periodic table, such as CIS or CIGS.

“I-II-IV-VI compound semiconductor” refers to compound semiconductor materials composed of group IB element, group IIB element, group IVA element and group VIA element of periodic table, such as CZTS.

“Fullerene” refers to a carbon molecule formed with a cage-like fused ring polycyclic structure, including five-membered and six-membered rings. For example, fullerene can be a C60 molecule, which includes 60 carbon atoms configured in a truncated icosahedron.

“Functional group” refers a specific group of bound atoms within organic molecules that are responsible for characteristic chemical reactions of those molecules.

“Oxoacid” refers to an acid containing an oxygen.

“Thin film chalcogen photovoltaic device” refers to thin film photovoltaic device which uses a thin film containing chalcogenide semiconductor material as an active layer.

### Functional Groups:

“Acyl” refers to a functional group derived by removal of one or more hydroxyl groups from an oxoacid. For example, a carboxylic acid (RCOOH) has an acyl group (RCO—).

“Acylamino” refers to a functional group derived by removal of a hydrogen atom from nitrogen in an organic acid amide. For example, an acetamide (CH₃CONH₂) has an acylamino group (CH₃CONH—).

“Acyloxy” refers to a functional group derived by removal of a hydrogen atom from oxygen in an organic acid. For example, an acetic acid (CH₃COOH) has an acyloxy group (CH₃COO—).

“Alkenyl” refers to a functional group derived by removal of a hydrogen atom from an alkene. For example, an alkenyl group includes ethenyl, propenyl and butenyl, etc.

“Alkoxy” refers to an alkyl group singular bonded to oxygen. For example, a methoxy (CH₃O—) group is derived from a methyl group (CH₃—) bonded to oxygen.

“Alkyl” refers to a functional group derived by removal of a hydrogen atom from an alkane. For example, an alkyl group includes methyl, ethyl, n-propyl, iso-propyl, n-butyl and t-butyl, etc.

“Alkynyl” refers to a functional group derived from removal of a hydrogen atom from an alkyne. For example, an alkynyl group includes propynyl and butynyl, etc.

“Amino” refers to a functional group having the formula of “—NH₂”.

“Aminoacyl” refers to a functional group derived from removal of a hydroxyl group from the carboxyl group in an amino acid. For example, an alpha amino acid (H₂NCHRCOOH) includes an aminoacyl group (H₂NCHRCO—).

“Aryl” refers to a functional group derived from an aromatic ring. For example, an aryl group includes phenyl, naphthyl, thienyl, indolyl, etc.

“Aryloxy” refers to an aryl group bonded to an oxygen. For example, a phenoxy group (—C₆H₅O) is derived from a phenyl group bonded to an oxygen.

“Carboxyl” refers to a functional group having a formula of “—COOH”.

“Carboxyl esters” refers to an organic compound derived from replacing a hydrogen with a hydrocarbon group in a carboxylic acid.

“Cyano” refers a functional group having a formula of “—C≡N”.

“Cycloalkoxy” refers to a cycloalkyl group bonded to an oxygen. For example, a cyclopentyloxy (—O—C₅H₉) group is derived from a cyclopentyl group bonded to an oxygen.

“Cycloalkyl” refers to a functional group derived from removal of a hydrogen atom from a cycloalkane. For example, a cycloalkyl group includes cyclopentyl, or cyclohexyl, etc.

“Halo” refers to a halogen substituent, including fluoro, chloro, bromo and iodo.

“Heteroaryl” refers to a functional group derived from an aromatic ring having at least two different atoms as members of the ring. For example, a heteroaryl group includes pyrrolyl, or imidazolyl, etc.

“Heteroaryloxy” refers to a heteroaryl group bonded to an oxygen. For example, a pyridyloxy group is derived from a pyridyl group bonded to an oxygen.

“Heterocyclic” refers to a functional group derived from a cyclic ring having at least two different atoms as members of the ring. For example, imidazolidinyl or pyrrolidinyl, etc.

“Heterocyclyloxy” refers to a heterocyclic group bonded to an oxygen. For example, an imidazolidinyloxy group is derived from an imidazolidinyl group bonded to an oxygen.

“Nitro” refers to a nitrogen substituent.

“Substituted alkenyl” refers to an alkenyl group having at least one substituent.

“Substituted alkoxy” refers to an alkoxy group having at least one substituent.

“Substituted alkyl” refers to an alkyl group having at least one substituent.

“Substituted alkynyl” refers to an alkynyl group having at least one substituent.

“Substituted amino” refers to an amino group having at least one substituent.

“Substituted aryl” refers to an aryl group having at least one substituent.

“Substituted aryloxy” is a functional group having at least one substituent.

“Substituted cycloalkoxy” refers to a cycloalkoxy group having at least one substituent.

“Substituted cycloalkyl” refers to a cycloalkyl group having at least one substituent.

“Substituted heteroaryl” refers to a heteroaryl group having at least one substituent.

“Substituted heteroaryloxy” refers to a heteroaryloxy group having at least one substituent.

“Substituted heterocyclic” refers to a heterocyclic group having at least one substituent.

“Substituted heterocyclyloxy” refers to a heterocyclyloxy group bonded to an oxygen.

“Substituted thioalkyl” refers to a thioalkyl group having at least one substituent.

“Substituted thioaryl” refers to a thioaryl group having at least one substituent.

“Substituted thioheteroaryl” refers to a thioheteroaryl group having at least one substituent.

“Substituted thiocycloalkyl” refers to a thiocycloalkyl group having at least one substituent.

“Substituted thioheterocyclic” refers to a thioheterocyclic group having at least one substituent.”

“Thienyl” refers to a functional group having a formula of C₄H₃S, which is derived from removal of a hydrogen atom from thiophene.

“Thioalkyl” refers to an alkyl group bonded to a sulfur. For example, thiomethyl group (—S—CH₃) is derived from a methyl group bonded to a sulfur.

“Thioaryl” refers to an aryl group bonded to a sulfur. For example, a thiophenyl group (—S—C₆H₅) is derived from a phenyl group bonded to a sulfur.

“Thiocycloalkyl” refers to a cycloalkyl group bonded to a sulfur. For example, a thiocyclopentyl group (—S—C₅H₉) is derived from a cycloalkyl group bonded to a sulfur.

“Thioheteroaryl” refers to an heteroaryl group bonded to a sulfur. For example, a thiopyrrolyl group (—S—C₄H₄N) is derived from a pyrrolyl group bonded to a sulfur.

“Thioheterocyclic” refers to a heterocyclic ring bonded to a sulfur. For example, a thioimidazolidinyl group (—S—C₃H₇N₂) is derived from an imidazolidinyl group bonded to a sulfur.

“Thiol” refers to a functional group having a formula of “—SH”.

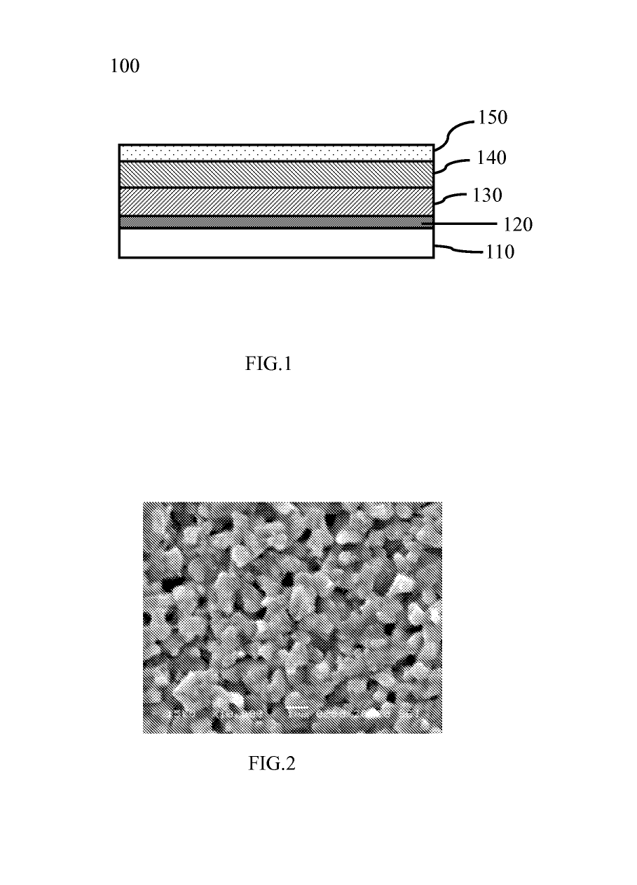

Referring to FIG. 1, it is a front view of a conventional thin film chalcogenide photovoltaic device. As shown in FIG. 1, the conventional thin film chalcogenide photovoltaic device 100 includes a substrate 110, a first electrode 120, a p-type chalcogenide semiconductor layer 130, an n-type inorganic semiconductor layer 140 and a second electrode layer 150. The substrate 110 includes an insulating substrate or a conductive substrate. The substrate 110 also can be rigid or flexible. For example, the substrate 110 can be, but not limited to, glass, ceramic, metal foil or plastic. The first electrode 120 includes a material selected from a group consisted of molybdenum (Mo), tungsten (W), aluminum (Al), and indium tin oxide (ITO). The p-type chalcogenide semiconductor layer 130 includes I-III-VI or I-II-IV-VI compound semiconductors. For example, the p-type chalcogenide semiconductor layer 130 can be, but not limited to, CIS, CIGS or CZTS. The n-type inorganic semiconductor layer 140 can be, but not limited to, cadmium sulfide (CdS), Zn(O,OH,S), indium Sulfide (In₂S₃), zinc sulfide (ZnS) or zinc magnesium oxide (ZnₓMg₁₋ₓO). The second electrode 150 includes a transparent conductive layer. Preferably, the transparency of the second electrode at 550 nm is greater than or equal to 50%. For example, the second electrode 150 includes a material selected from a group consisted of zinc oxide (ZnO), indium tin oxide (ITO), boron-doped zinc oxide (B—ZnO), aluminum-doped zinc oxide (Al—ZnO), gallium-doped zinc oxide (Ga—ZnO), and antimony tin oxide (ATO).

In the thin film chalcogenide semiconductor photovoltaic device 100, the p-type chalcogenide semiconductor layer 130 is usually formed as a polycrystalline thin film and composed of crystallite grains of varying size and orientation. It is usually some structural defects, such as fractures, formed in the p-type chalcogenide semiconductor layer. The fractures formed between neighboring crystallite grains are generally referred to grain boundaries. Besides, when the p-type chalcogenide semiconductor layer 130 is processed with high-temperature treatment, such as an annealing process, it is usually cracked and formed with many voids. A SEM picture of a CZTS thin film is shown in FIG. 2. As shown in FIG. 2, it is not smooth on the surface of the CZTS thin film. Instead, the CZTS thin film is cracked into a rough film and has voids formed on its surface. When it is used as the p-type chalcogenide semiconductor layer 130 in the thin film chalcogenide photovoltaic device 100, the CZTS thin film and the n-type inorganic semiconductor layer 140, such as CdS, cannot form uniform contact since the CdS layer 140 is usually formed by a chemical bath deposition (CBD) method and is not able to fill into the voids during its deposition process.

Therefore, the present application disclosed a method of solving the problem mentioned above.

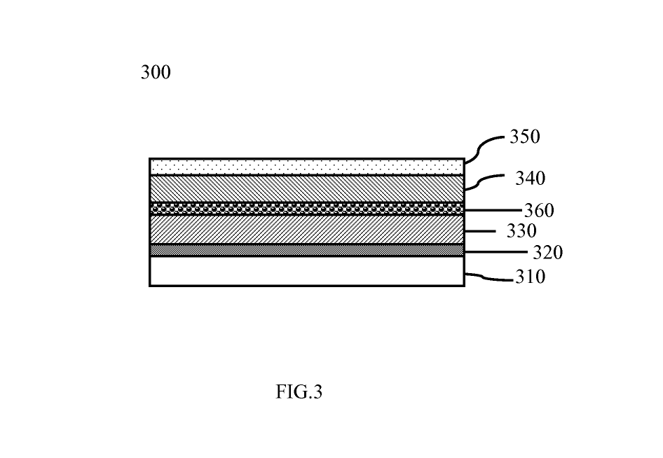

Referring to FIG. 3, it is a front view of the thin film chalcogenide photovoltaic device of the present application. The thin film chalcogenide photovoltaic device 300 includes a substrate 310, a first electrode 320, a p-type chalcogenide semiconductor layer 330, an n-type inorganic semiconductor layer 340, a second electrode 350 and an n-type carbon-containing material layer 360. The n-type carbon-containing material layer 360 is disposed between the p-type chalcogenide semiconductor layer 330 and the n-type inorganic semiconductor layer 340. The p-type chalcogenide semiconductor layer 330, the n-type carbon-containing material layer 360 and the n-type inorganic semiconductor layer 340 constitute an active layer.

The structure of the thin film chalcogenide photovoltaic device 300 is similar to the thin film chalcogenide photovoltaic device 100 except the n-type carbon-containing material layer 360.

The substrate 310 includes an insulating substrate or a conductive substrate. The substrate 310 also can be rigid or flexible. For example, the substrate 310 can be, but not limited to, glass, ceramic, metal foil or plastic. The first electrode 320 includes a material selected from a group consisted of molybdenum (Mo), tungsten (W), aluminum (Al), and indium tin oxide (ITO). The p-type chalcogenide semiconductor layer 330 includes I-III-VI or I-II-IV-VI compound semiconductors. For example, the p-type chalcogenide semiconductor layer 330 can be, but not limited to, CIS, CIGS or CZTS. The n-type inorganic semiconductor layer 340 can be, but not limited to, cadmium sulfide (CdS), Zn(O,OH,S), indium Sulfide (In₂S₃) zinc sulfide (ZnS) or zinc magnesium oxide (ZnₓMg₁₋ₓO). The second electrode 350 includes a transparent conductive layer. For example, the top electrode layer 350 includes a material selected from a group consisted of zinc oxide (ZnO), indium tin oxide (ITO), boron-doped zinc oxide (B—ZnO), aluminum-doped zinc oxide (Al—ZnO), gallium-doped zinc oxide (Ga—ZnO), and antimony tin oxide (ATO).

The n-type carbon-containing material layer 360 includes an n-type material which can be used to fill the structural defects in the p-type chalcogenide semiconductor layer 330 and facilitates electron extraction in the structural defects of the p-type chalcogenide semiconductor layer 330. In some embodiments, the n-type carbon-containing material layer 360 can be formed as an ultra-thin layer with molecular level thickness. For example, the n-type carbon-containing material can be, but not limited to, fullerene material, n-type carbon nanotubes, siloles (silacyclopentadienes), rylene diimides and n-type acenes.

In some embodiments, the n-type carbon-containing material layer 360 is formed before an annealing process of the p-type chalcogenide semiconductor layer 330. Under such a circumstance, the fullerene material can be used as the n-type carbon-containing material layer 360 since it is endurable under high temperature treatment. In other embodiments, the fullerene material also can be formed after the annealing process of the p-type chalcogenide semiconductor layer.

The fullerene material includes at least a fullerene derivative having a formula of:

F—(R)ₙ;

wherein F is fullerene, R includes a first ring which is carbocyclic or heterocyclic and boned to the fullerene, and n is an integer, which n≧0.

In some embodiments, the fullerene material can be a molecule composed entirely of carbon. For example, when n is zero, the fullerene material can be, but not limited to, C60 fullerene (C60), C70 fullerene (C70), or C84 fullerene (C84). When n is greater than zero, the fullerene derivative includes a fullerene cage and at least one functional group “R” bonded to the fullerene cage. Herein, the fullerene cage refers to the carbon cluster of the fullerene derivative. The R group includes at least a first ring. The first ring of the R group can be a three-membered, four-membered, five-membered or six-membered ring, for example. The first ring can be carbocyclic or heterocyclic. For example, the first ring can be, but not limited to, cyclopropyl, cyclobutyl, cyclopentyl or cyclohexyl.

The possible substituents of the first ring of the R group include at least one selected from the group consisted of hydroxy, acyl, acylamino, acyloxy, alkyl, substituted alkyl, alkoxy, substituted alkoxy, alkenyl, substituted alkenyl, alkynyl, substituted alkynyl, amino, substituted amino, aminoacyl, aryl, substituted aryl, aryloxy, substituted aryloxy, cycloalkoxy, substituted cycloalkoxy, carboxyl, carboxyl esters, cyano, thiol, thioalkyl, substituted thioalkyl, thioaryl, substituted thioaryl, thioheteroaryl, substituted thioheteroaryl, thiocycloalkyl, substituted thiocycloalkyl, thioheterocyclic, substituted thioheterocyclic, cycloalkyl, substituted cycloalkyl, halo, nitro, heteroaryl, substituted heteroaryl, heterocyclic, substituted heterocyclic, heteroaryloxy, substituted heteroaryloxy, heterocyclyloxy, or substituted heterocyclyloxy, or a combination thereof.

The first ring of the R group also can be an unsaturated or saturated ring. For example, the fullerene derivative can be 1,2-(3,4-Dihydro-2H-pyrrolo)-[60]fullerene.

Besides, the R group can further include a second ring which is carbocyclic or heterocyclic ring, and bonded to or fused with the first ring. For example, the fullerene derivative can be indene-C60. For more examples, the fullerene derivative can be, but not limited to, [6,6]-phenyl C61 butyric acid methyl ester ([60]PCBM), [6,6]-phenyl C71 butyric acid methyl ester ([70]PCBM), [6,6]-phenyl C85 butyric acid methyl ester ([84]PCBM), [6,6]-phenyl C61 butyric acid dodecyl ester (PCBD), [6,6]-phenyl C61 butyric acid octadecyl ester (PCBOD), [6,6]-phenyl-C61-butyric-acid-butyl ester (PCBB), thienyl-C61-butyric-acid-methyl ester (TCBM), mono-o-quino-dimethane C60 (oQDMC60), bis-[6,6]-phenyl C61 butyric acid methyl ester (bis-[60]PCBM), tris-[6,6]-phenyl C61 butyric acid methyl ester (tris-[60]PCBM), tetra-[6,6]-phenyl C61 butyric acid methyl ester (tetra-[60]PCBM), {(methoxycarbonyl)phenyl[bis(octyloxy)phenyl]-methano}fullerene, bis-o-Quino-Dimethane C60 (bis-oQDMC60).

Besides, the fullerene derivative with two or more R groups.

In other embodiments, the n-type carbon-containing material layer 360 can be formed after an annealing process of the p-type chalcogenide semiconductor layer 330. Then, the n-type carbon-containing material layer 360 can be, for example, but not limited to, n-type carbon nanotube, siloles (silacyclopentadienes), rylene diimides and n-type acenes.

The siloles, i.e., silacyclopentadienes, can be, for example, 1,1-dimethyl-2,3,4,5-tetraphenylsilole, or hexaphenylsilole.

The rylene diimides can be, for example, but not limited to, naphthalene diimides or perylene diimides.

The n-type acenes can be, for example, but not limited to, perfluoropentacene or perfluorotetracene.

In some embodiment, the n-type carbon-containing material layer 360 can be formed on the surface of the p-type chalcogenide semiconductor layer 330 by a solution process. The n-type carbon-containing material 360 can be dissolved into a solvent and coated onto the surface of the p-type chalcogenide semiconductor layer 330. Therefore, the n-type carbon-containing material 360 can be dissolved as well-dispersed molecules in the solvent and fill into the voids of the p-type chalcogenide semiconductor layer 330. Especially, the n-type carbon-containing material 360 can cover the grain boundaries of the p-type chalcogenide semiconductor layer 330. Thus, the problem mentioned above can be solved. In other embodiments, the n-type carbon-containing material layer 360 can be formed by other methods, such as, but not limited to, thermal evaporation.

A method of forming the thin film chalcogenide photovoltaic device 300 will be described below.

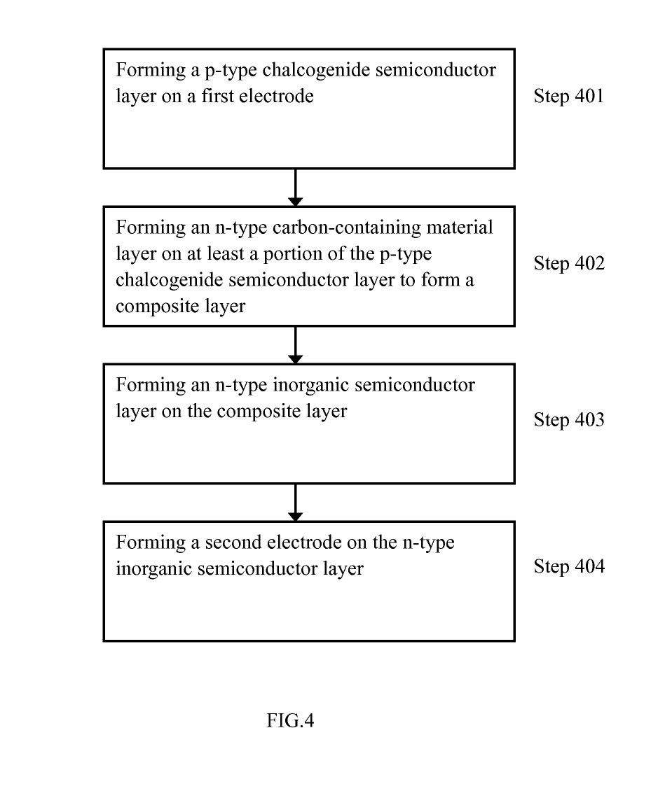

Referring to FIG. 4, it is a flow chart of a method of forming the thin film chalcogenide photovoltaic device according to an embodiment of the present application.

Step 401 includes forming a p-type chalcogenide semiconductor layer on a first electrode. The first electrode can be formed on a substrate first. The p-type chalcogenide semiconductor layer can be, for example, a CZTS thin film. The CZTS thin film can be formed by, such as, but not limited to, a solution process. A precursor solution, i.e., an ink, of CZTS can be coated onto the first electrode to form a liquid layer. The liquid layer is dried to form a CZTS precursor layer on the first electrode. Then, the CZTS precursor layer is annealed and crystallized into a CZTS film.

Step 402 includes forming an n-type carbon-containing material layer on at least a portion of the p-type chalcogenide semiconductor layer to form a composite layer. The composite layer is constituted by the p-type chalcogenide semiconductor layer and the n-type carbon-containing material layer. The n-type carbon-containing material layer can be formed by, for example, but not limited to, dissolving PCBM in dichlorobenzene (DCB) to form a PCBM solution, coating the PCBM solution on the surface of the p-type chalcogenide semiconductor layer and drying the PCBM solution to form a PCBM layer on the p-type chalcogenide semiconductor layer.

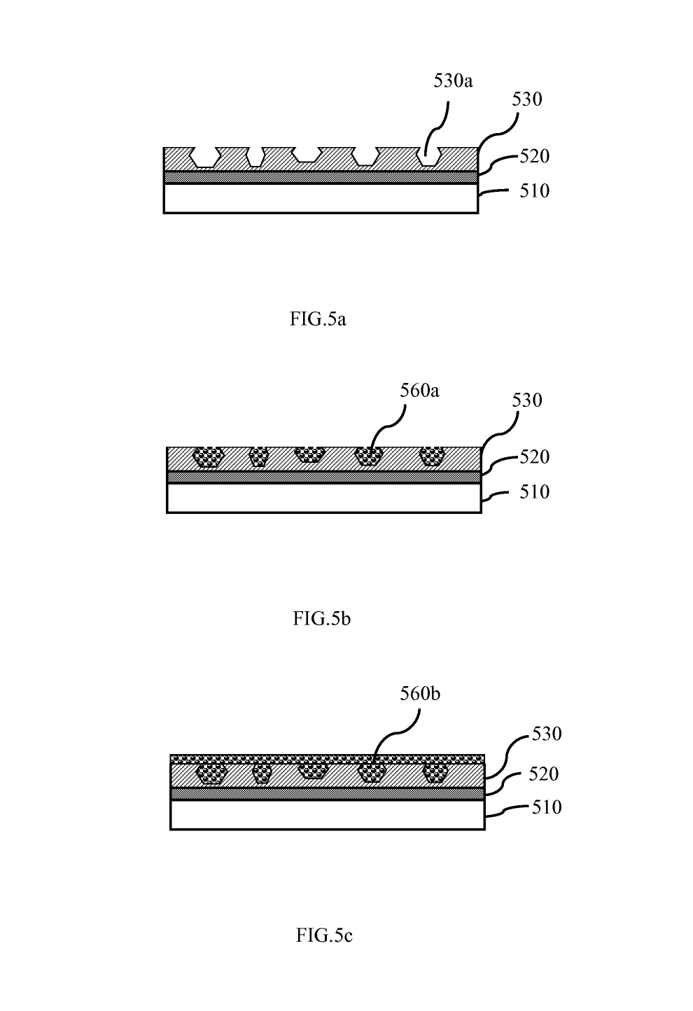

Referring to FIG. 5a, FIG. 5b and FIG. 5c, these are enlarged sectional view of the thin film chalcogenide photovoltaic device of the present application. As shown in FIG. 5a, the p-type chalcogenide semiconductor layer 530 includes voids 530a after an annealing process. Also referring to FIG. 5b, in one embodiment, after step 402, the n-type carbon-containing material 560a is filled into the voids 530a and/or grain boundaries of the p-type chalcogenide semiconductor layer 530. In the embodiment shown in FIG. 5b, the n-type carbon-containing material layer refers to the n-type carbon-containing material 560a filled in the voids 530a and/or grain boundaries (not shown) of the p-type chalcogenide semiconductor layer 530. While in another embodiment, as shown in FIG. 5c, the n-type carbon-containing material is not only filled into voids 530a and/or grain boundaries but also formed as a layer 560b on the p-type chalcogenide semiconductor layer 530. That is, in the embodiment shown in FIG. 5c, the n-type carbon material layer refers to the carbon-containing material 560a filled in the voids 530a and/or grain boundaries of the p-type chalcogenide semiconductor layer 530 and the layer 560b formed on the p-type chalcogenide semiconductor layer 530.

Step 403 includes forming an n-type inorganic semiconductor layer on the composite layer. The n-type inorganic semiconductor layer can be formed by, for example, but not limited to, depositing a CdS layer by chemical bath deposition method. In some embodiments, such as FIG. 5b, the n-type carbon-containing material is only formed in the voids 530a and/or grain boundaries of the p-type chalcogenide semiconductor layer 530, and the n-type inorganic semiconductor layer is formed directly on the p-type chalcogenide semiconductor layer. Or, in other embodiments, the n-type inorganic semiconductor layer is formed directly on the n-type carbon-containing material layer.

Step 404 includes forming a second electrode on the n-type inorganic semiconductor layer. The second electrode can be formed by, for example, forming an ITO layer by sputtering.

### EXAMPLES

Hereinafter, several examples will be described in order to provide a better understanding of the present application.

### Example 1

In Example 1, several thin film chalcogenide photovoltaic devices (sample 1 to sample 4) were prepared with different structures. A basic structure of sample 1 to sample 4 includes a first electrode, a p-type chalcogenide semiconductor layer, an n-type inorganic semiconductor layer and a second electrode. The basic structure was also used as sample 1's device structure. In sample 2 to sample 4, an n-type carbon-containing material layer was formed between the p-type chalcogenide semiconductor layer and the n-type inorganic semiconductor layer. Referring to Table 1, the structural differences of sample 1 to sample 4 were listed in the table. These samples were prepared to identify an efficiency of employing the n-type carbon-containing material layer.

Each of the layers of sample 1 to sample 4 was manufactured by the following methods.

Method for forming a first electrode: A Mo layer having a thickness of about 850 nm to about 900 nm was formed as a first electrode on a glass substrate. The Mo layer can be formed, for example, by a sputtering process.

Method for forming the p-type chalcogenide semiconductor layer: A CZTS precursor solution was prepared first. The CZTS precursor solution can be prepared as follows: (a) 1.29 mmol of SnCl₂ was dissolved in 1.5 ml of water and stirred for 5 minutes to form a solution (A1), 0.45 g of thiourea was dissolved in 3 ml of water to form a solution (B1) and then the solution (A1) and the solution (B1) were mixed and stirred for 5 minutes to form a solution (C1). (b) 1.65 mmol of Cu(NO₃)₂ was dissolved in 1 ml of water to form a solution (D1), 1.38 mmol of Zn(NO₃)₂ was dissolved in 1 ml of water to form a solution (E1), and then the solution (C1), the solution (D1) and the solution (E1) were mixed and stirred at 90° C. for 5 minutes to form a solution (F1). (c) 1.8 ml of (NH₄)₂S aqueous solution was added into the solution (F1) and stirred overnight or under sonication for 30 minutes to form the CZTS precursor solution. Then, the CZTS precursor solution was coated onto the Mo layer by spin coating method. The coated CZTS precursor solution was then dried at 210° C. for 4 minutes and 425° C. for 2 minutes sequentially. The coating and drying process were repeated for about 8 times to obtain a precursor film with a thickness of about 1.6 μm. Then, the precursor film is crystallized into a CZTS thin film under an annealing temperature of about 600° C. for 14 minutes. The CZTS thin film was further baked at 150° C. for 5 minutes.

Method of forming the n-type inorganic semiconductor layer: A CdS layer was formed on the CZTS thin film. The CdS layer can be formed, for example, by a chemical bath deposition method (CBD). A thickness of the CdS layer can be of about 50 nm, for example.

Method of forming the n-type carbon-containing material layer: Before forming the CdS layer, 7 mg or 14 mg of PCBM was dissolved in 1 ml of dichlorobenzene and then coated onto the CZTS thin film. The PCBM can be coated by a spin-coating method, for example. The spin-coating method of the PCBM can be 3000 rpm for 60 seconds or 5000 rpm for 60 seconds.

Method of forming the second electrode: A ZnO layer and a ITO layer were formed on the CdS layer sequentially. The ZnO and ITO layers can be formed, for example, by sputtering. The thickness of the ZnO layer can be of about 100 nm and the thickness of the ITO layer can be of about 150 nm, for example.

Method of forming metal contacts: A silver layer was formed and patterned on the ITO layer to form metal contacts.

Referring to Table 2, the characteristics such as fill factor, open circuit voltage (V_{oc}) and cell efficiency, etc of sample 1 to sample 4 are listed in the table. According to the data shown in the Table 2, it can be found that sample 2, sample 3 and sample 4 all have lowered series resistance (Rₛ), higher short circuit current density (J_{sc}) and better cell efficiencies. That is, a thin film chalcogenide photovoltaic device with PCBM treatment can have a better performance than those photovoltaic devices without PCBM treatment.

TABLE 1

| Thickness/Amount | Sample 1 | Sample 2 | Sample 3 | Sample 4 |
|---|---|---|---|---|
| Mo layer | 850 nm | 850 nm | 850 nm | 850 nm |
| CZTS layer | 1.6 μm | 1.6 μm | 1.6 μm | 1.6 μm |
| PCBM | 0 | 14 mg/ | 7 mg/ | 14 mg/ |
| | | in 1 mL | in 1 mL | in 1 mL |
| | | DCB | DCB | DCB |
| PCBM | 0 | 3000 rpm | 3000 rpm | 5000 rpm |
| spin-coating speed | | | | |
| CdS layer | 50 nm | 50 nm | 50 nm | 50 nm |
| ZnO/ITO | 100 nm/150 nm | 100 nm/ | 100 nm/ | 100 nm/ |
| | | 150 nm | 150 nm | 150 nm |

TABLE 2

| | Sample 1 | Sample 2 | Sample 3 | Sample 4 |
|---|---|---|---|---|
| Fill Factor (%) | 54.99 | 53.73 | 54.48 | 57.16 |
| V_{oc} (V) | 0.58 | 0.57 | 0.58 | 0.57 |
| Iₘₚ (mA) | 6.18 | 6.72 | 6.99 | 6.24 |
| Cell eff. (%) | 7.17 | 7.59 | 8.11 | 7.42 |
| J_{sc} (mA/cm²) | 22.59 | 24.61 | 25.69 | 22.85 |
| Rₛₕₒᵣₜ (Rₛ) | 28.90 | 27.24 | 25.85 | 25.48 |
| Rₛₕᵤₙₜ (Rₛₕ) | 290.78 | 255.16 | 252.75 | 301.85 |

### Example 2

In Example 2, several thin film chalcogenide photovoltaic devices (sample 5 to sample 7) were prepared with similar structures and different thickness of n-type inorganic semiconductor layer. Each of samples 5 to 7 includes a first electrode, a p-type chalcogenide semiconductor layer, an n-type carbon-containing material layer, an n-type inorganic semiconductor layer and a second electrode. The manufacturing method for each layer can follow the steps shown in Example 1. The difference between samples 5 to 7 is the thickness of the n-type inorganic semiconductor layer. Referring to Table 3, the structural differences of samples 5 to 7 were listed in the table. These samples were prepared to identify a benefit of employing the n-type carbon-containing material layer in reducing the thickness of the n-type inorganic semiconductor layer.

TABLE 3

| Thickness/Amount | Sample 5 | Sample 6 | Sample 7 |
|---|---|---|---|
| Mo layer | 850 nm | 850 nm | 850 nm |
| CZTS layer | 1.6 μm | 1.6 μm | 1.6 μm |
| PCBM | 14 mg/in 1 mL | 14 mg/in 1 mL | 14 mg/in 1 mL |
| | DCB | DCB | DCB |
| PCBM | 3000 rpm | 3000 rpm | 3000 rpm |
| spin-coating speed | | | |
| CBD deposition | 11.5 minutes | 10 minutes | 9 minutes |
| time for | | | |
| CdS layer | | | |
| ZnO/ITO | 100 nm/150 nm | 100 nm/150 nm | 100 nm/150 nm |

Referring to Table 4, the characteristic of each of the devices of samples 5 to 7 were listed in the table. According to the data shown in the table, sample 6 and sample 7 which had shorter deposition time of CdS, i.e., a thinner thickness of CdS, both have better cell efficiencies than sample 5. Therefore, it was proved that a PCBM treatment on the thin film chalcogenide photovoltaic device can use a thinner n-type inorganic semiconductor layer as comparing to conventional devices.

TABLE 4

| | Sample 5 | Sample 6 | Sample 7 |
|---|---|---|---|
| Fill Factor (%) | 56.98 | 53.85 | 56.66 |
| V_{oc} (V) | 0.53 | 0.52 | 0.54 |
| Iₘₚ (mA) | 6.45 | 6.82 | 7.03 |
| Cell eff. (%) | 7.10 | 7.12 | 7.74 |
| J_{sc} (mA/cm²) | 23.40 | 25.34 | 25.34 |
| Rₛₕₒᵣₜ (Rₛ) | 23.40 | 23.41 | 22.78 |
| Rₛₕᵤₙₜ (Rₛₕ) | 283.54 | 216.81 | 267.02 |

Although illustrative embodiments of the present application have been described herein, it is to be understood that the present application is not limited to those embodiments, and that various other changes and modifications may be made by one skilled in the art without departing from the scope of the present application.

What is claimed is:

1. A thin film chalcogenide photovoltaic device, comprising:
a first electrode;
a second electrode; and
an active layer disposed between the first electrode and the second electrode, including
a p-type chalcogenide semiconductor layer;
an n-type inorganic semiconductor layer; and
an n-type carbon-containing material layer, formed between the p-type chalcogenide semiconductor layer and the n-type inorganic semiconductor layer.

2. The thin film chalcogenide photovoltaic device according to claim 1, wherein the n-type carbon-containing material layer is adapted to facilitate electron extraction in structural defects of the p-type chalcogenide semiconductor layer.

3. The thin film chalcogenide photovoltaic device according to claim 1, wherein the p-type chalcogenide semiconductor layer includes at least one selected from the group consisted of I-III-VI and I-II-IV-VI compound semiconductor.

4. The thin film chalcogenide photovoltaic device according to claim 3, wherein the I-III-VI compound semiconductor includes CIS and CIGS.

5. The thin film chalcogenide photovoltaic device according to claim 3, wherein the I-II-IV-VI compound semiconductor includes CZTS.

6. The thin film chalcogenide photovoltaic device according to claim 1, wherein the n-type carbon-containing material layer includes fullerene material, n-type carbon nanotubes, siloles, rylene diimides, or n-type acenes.

7. The thin film chalcogenide photovoltaic device according to claim 6, wherein the fullerene material includes a fullerene derivative represented by:
F—(R)ₙ
wherein F is fullerene, R includes a first ring which is carbocyclic or heterocyclic, and boned to the fullerene, and n is an integer, wherein n≧0.

8. The thin film chalcogenide photovoltaic device according to claim 7, wherein the first ring is a three-membered, four-membered, five-membered, or six-membered ring.

9. The thin film chalcogenide photovoltaic device according to claim 7, wherein the first ring is cyclopropyl, cyclobutyl, cyclopentyl or cyclohexyl.

10. The thin film chalcogenide photovoltaic device according to claim 7, wherein the first ring further includes at least one substituent selected from the group consisted of hydroxy, acyl, acylamino, acyloxy, alkyl, substituted alkyl, alkoxy, substituted alkoxy, alkenyl, substituted alkenyl, alkynyl, substituted alkynyl, amino, substituted amino, aminoacyl, aryl, substituted aryl, aryloxy, substituted aryloxy, cycloalkoxy, substituted cycloalkoxy, carboxyl, carboxyl esters, cyano, thiol, thioalkyl, substituted thioalkyl, thioaryl, substituted thioaryl, thioheteroaryl, substituted thioheteroaryl, thiocycloalkyl, substituted thiocycloalkyl, thioheterocyclic, substituted thioheterocyclic, cycloalkyl, substituted cycloalkyl, halo, nitro, heteroaryl, substituted heteroaryl, heterocyclic, substituted heterocyclic, heteroaryloxy, substituted heteroaryloxy, heterocyclyloxy, substituted heterocyclyloxy and a combination thereof.

11. The thin film chalcogenide photovoltaic device according to claim 7, wherein R further includes a second ring which is carbocyclic or heterocyclic ring, and bonded or fused with the first ring.

12. The thin film chalcogenide photovoltaic device according to claim 7, wherein the fullerene material includes C60, C70, C84, PCBM, PCBD, PCBOD, PCBB, TCBM, oQDMC60, or indene-C60.

13. The thin film chalcogenide photovoltaic device according to claim 1, wherein the n-type inorganic semiconductor layer includes at least one selected from the group consisted of cadmium sulfide (CdS), Zn(O,OH,S), indium selenide (In₂S₃), zinc sulfide (ZnS), zinc magnesium oxide (ZnₓMg₁₋ₓO), and a combination thereof.

14. The thin film chalcogenide photovoltaic device according to claim 1, wherein the first electrode includes at least one selected from the group consisted of molybdenum (Mo), doped molybdenum, tungsten (W), doped tungsten, aluminum (Al), doped aluminum, indium tin oxide (ITO), doped indium tin oxide and a combination thereof.

15. The thin film chalcogenide photovoltaic device according to claim 1, wherein the second electrode is transparent and transparency of the second electrode at 550 nm is greater than or equal to 50%.

16. The thin film chalcogenide photovoltaic device according to claim 1, wherein the second electrode includes at least one selected from the group consisted of zinc oxide (ZnO), indium tin oxide (ITO), boron-doped zinc oxide (B—ZnO), aluminum-doped zinc oxide (Al—ZnO), gallium-doped zinc oxide (Ga—ZnO), antimony tin oxide (ATO), and a combination thereof.

17. A method for forming a thin film chalcogenide photovoltaic device, comprising:
forming a p-type chalcogenide semiconductor layer on a first electrode;
forming an n-type carbon-containing material layer on at least a portion of the p-type chalcogenide semiconductor layer to form a composite layer constituted by the p-type chalcogenide semiconductor layer and the n-type carbon-containing material layer;
forming an n-type inorganic semiconductor layer on the composite layer; and
forming a second electrode on the n-type inorganic layer.

18. The method according to claim 17, wherein the step of forming the n-type carbon-containing material layer includes filling the n-type carbon-containing material into structural defects of the p-type chalcogenide semiconductor layer.

19. The method according to claim 17, wherein the step of forming the n-type carbon-containing material layer includes using at least one material selected from the group consisted of fullerene material, n-type carbon nanotubes, siloles, rylene diimides and n-type acenes.

20. The method according to claim 17, wherein the step of forming the n-type carbon-containing material layer includes coating or thermal evaporation.
